(19) United States
(12) Patent Application Publication
(10) Pub. No.: US 2024/0331989 A1
(43) Pub. Date: Oct. 3, 2024

(54) MINI SPECTROMETER SENSOR FOR IN-LINE, ON-TOOL, DISTRIBUTED DEPOSITION OR SPECTRUM MONITORING

(71) Applicant: Applied Materials, Inc., Santa Clara, CA (US)

(72) Inventor: Chuang-Chia Lin, San Ramon, CA (US)

(21) Appl. No.: 18/128,032

(22) Filed: Mar. 29, 2023

(51) Int. Cl. H01J 37/32; G01B 11/06; G01N 21/31; H01L 21/66

(52) U.S. Cl. CPC H01J 37/3299; G01B 11/06; G01N 21/31; H01L 22/26; H01J 37/3244

(57) ABSTRACT

Embodiments disclosed herein include a semiconductor processing tool. In an embodiment, the semiconductor processing tool comprises a chamber, and a diagnostic device integrated with the chamber. In an embodiment, the diagnostic device comprises a board, a spectrometer on the board, and a housing around the board.

### BACKGROUND

### 1) Field

Embodiments relate to the field of semiconductor manufacturing and, in particular, a sensor (or an array of sensors) integrated in a chamber for measuring surfaces and/or plasma parameters within the chamber.

### 2) Description of Related Art

In semiconductor manufacturing environments, chambers are typically used to deposit materials onto a substrate, etch materials on a substrate, or treat material layers on a substrate. During the various processing operations, characteristics of the chamber may change. For example, materials may be deposited onto the interior chamber surfaces. In some instances a layer may be a coating on the interior chamber surface. The coating may be partially etched or excess material may be deposited on the seasoning layer. Changes to the interior surfaces of the chamber would typically result in changes to the processing result of substrates processed in the chamber. As such, it is desirable to monitor the changes to the interior surfaces of the chamber.

In order to monitor conditions within the chamber, spectrometers, reflectometers or diagnostic substrates can be used. However, typical spectrometers (e.g., optical emission spectrometer (OES) sensors) are bulky and large instruments that are mounted on the outside of the chamber. Spectrometers are also limited to measuring properties of the plasma, and cannot provide information on chamber coatings. The optical path may pass through a window in the chamber. Some diagnostic substrates have also been developed in the past by integrating CMOS or CCD imagers on the substrate. However, such diagnostic substrates do not have the ability to analyze the optical beam to produce optical spectrums. As such, only limited detail of the chamber inner surface or volume can be obtained.

### SUMMARY

Embodiments disclosed herein include a semiconductor processing tool. In an embodiment, the semiconductor processing tool comprises a chamber, and a diagnostic device integrated with the chamber. In an embodiment, the diagnostic device comprises a board, a spectrometer on the board, and a housing around the board.

Embodiments disclosed herein also comprise a semiconductor processing tool that includes a chamber, and a set of diagnostic devices integrated with the chamber. In an embodiment, the integrated diagnostic devices are configured to provide layer thickness measurements, layer composition measurements, and/or plasma property measurements.

Embodiments disclosed herein also include a method of processing a semiconductor device. In an embodiment, the method comprises initiating a process in a chamber with an array of integrated diagnostic devices distributed through the chamber, using the array of diagnostic devices to generate feedback data that includes one or more of a material composition of a layer, a thickness of the layer, and a spectrum of a plasma in the chamber. In an embodiment, the method further comprises using the feedback data to control processing parameters of the process within the chamber.

### BRIEF DESCRIPTION OF THE DRAWINGS

FIG. 1A is a cross-sectional illustration of a sensor that may be used to monitor layers and/or plasma parameters within a processing chamber, in accordance with an embodiment.

FIG. 1B is a cross-sectional illustration of a sensor with components on both sides of the board, in accordance with an embodiment.

FIG. 1C is a plan view illustration of a sensor with an optically clear window, in accordance with an embodiment.

FIG. 2 is a cross-sectional illustration of a sensor with multiple light sources coupled to a single detector, in accordance with an embodiment.

FIG. 3 is a cross-sectional illustration of a chamber that includes a plurality of integrated sensors distributed throughout the chamber, in accordance with an embodiment.

FIG. 4A is a cross-sectional illustration of a gas line that includes deposits along an interior surface, in accordance with an embodiment.

FIG. 4B is a cross-sectional illustration of a gas line with an integrated sensor, in accordance with an embodiment.

FIG. 4C is a cross-sectional illustration of a gas line with a sensor that is provided over a window of the gas line, in accordance with an embodiment.

FIG. 5 is a plan view illustration of a sensor with a single light source that is coupled to a plurality of repeaters, in accordance with an embodiment.

FIG. 6 is a cross-sectional illustration of a chamber that has sensors that are coupled to a controller, in accordance with an embodiment.

FIG. 7 is a process flow diagram that depicts a process for controlling process parameters in response to feedback data generated by an array of sensors, in accordance with an embodiment.

FIG. 8 illustrates a block diagram of an exemplary computer system that may be used in conjunction with a processing tool, in accordance with an embodiment.

### DETAILED DESCRIPTION

Systems described herein include a sensor substrate that includes a reflectometer or spectrometer for measuring surfaces or plasma within a chamber. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, careful monitoring of the interior surfaces or volume of a semiconductor processing chamber is necessary in order to maintain tightly controlled processing outputs. However, existing chamber monitoring solutions are limited. External optical emission spectroscopy (OES) sensors may be mounted on the wall to include an optical path that passes through a window in the chamber. As such, the location of the chamber that is monitored is limited to the optical path that passes through the window. As such, spatial monitoring within the chamber is not possible. Additionally, in existing diagnostic substrate devices, cameras or linear sensors are often used. Such cameras are limited to optical imaging (only detect light intensity, not measuring wavelength), and are therefore not suitable for detecting layer thicknesses or layer compositions.

Accordingly, embodiments disclosed herein include diagnostic devices or sensors that are capable of providing spectral reflectance analysis of interior chamber surfaces as well as providing enhanced detail (film thickness, refractive index, etc.) of the interior chamber layers. Embodiments may also allow for analyzing properties of a plasma that is formed within a chamber. In an embodiment, an array of sensors may be integrated throughout the chamber. The array of sensors allows for the monitoring of various surfaces within the chamber, as well as spatial differences in a plasma (e.g., center-to-edge variations). In an embodiment, the sensors may have a compact form factor and a robust housing that allows for integration in various locations (e.g., sidewalls, lids, liners, gas lines, etc.). That is, the sensors may be provided inside of the chamber as opposed to being located only outside of the chamber.

In an embodiment, sensors described herein include one or more integrated spectrometers. The spectrometers can detect a spectrum of light that is reflected off of the interior surface of the chamber to project to the sensor. Embodiments may include a plurality of light sources in order to provide spatial detail without the need to move the sensor. Unlike optical cameras, the use of spectrometers allows for detailed information about the interior surface layers (e.g., composition, thickness, etc.) to be obtained. Spectrometers may also be used to detect plasma properties. It is to be appreciated that spectral reflectances obtained by the sensors can be used to determine material composition. For example, different material compositions will have different refractive index that can be used for the material composition determination. Additionally, spectral reflectances can be used to measure layer thicknesses and/or to provide information about the plasma. In the case of plasma detection, the sensor may not need a light source, since the plasma emits lights which can be directly measured.

In an embodiment, a processing operation (e.g., an etch, a deposition, a treatment, etc.) may be implemented in a chamber. The processing operation may be controlled in part by feedback data generated by the array of sensors. For example, feedback data may be used in order to tune one or more processing parameters of the processing operation in order to provide a more optimal processing outcome.

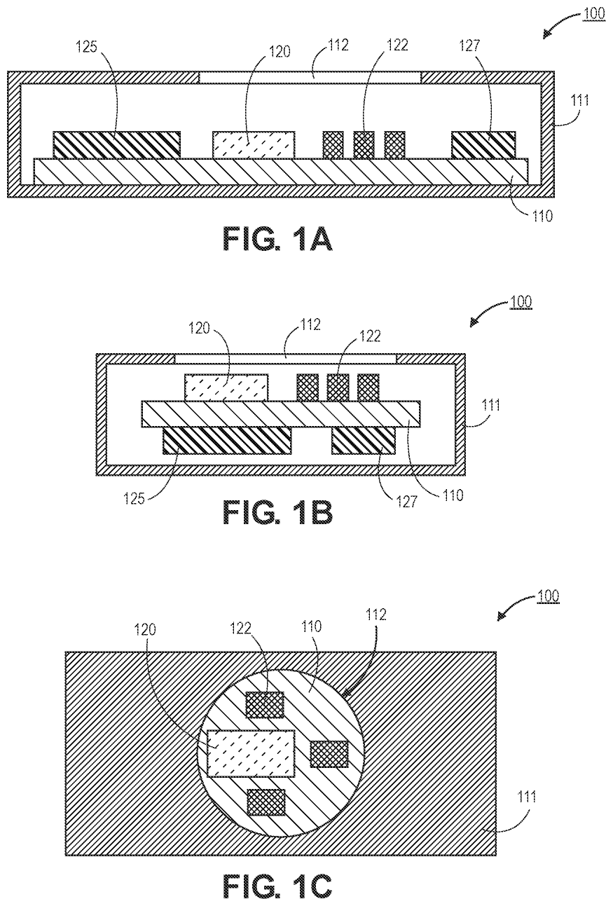

Referring now to FIG. 1A, a cross-sectional illustration of a sensor 100 is shown, in accordance with an embodiment. In an embodiment, the sensor 100 may comprise a board 110, such as a printed circuit board (PCB). The board 110 may include electrical routing (e.g., traces, pads, etc.) that is used for electrical coupling between components of the sensor 100.

In an embodiment, a spectrometer 120 is provided on the board 110. In an embodiment, the spectrometer 120 may be any suitable spectrometer architecture. The spectrometer 120 may be a low profile spectrometer 120. For example, a thickness of the spectrometer 120 may be approximately 5 mm or less, or approximately 1 mm or less. Similarly, a footprint of the spectrometer 120 may be relatively small as well. For example, the footprint may be approximately 20 mm by approximately 20 mm or smaller. In one embodiment, the footprint of the spectrometer 120 is approximately 5 mm by approximately 5 mm or smaller. The low profile and small footprint of the spectrometers 120 allows for the sensor 100 to be integrated into various locations within a processing chamber, as will be described in greater detail below. In an embodiment, any spectrometer 120 type that can be fabricated as a low-profile and small footprint device may be used. For example, the spectrometer 120 may include diffraction and/or a grating type spectrometers, photonic crystal and/or a filter type spectrometers, multi-spectral imager type spectrometers, or interferometer based spectrometers. In an embodiment, the spectrometer 120 may be replaced with a reflectometer, or both a spectrometer 120 and a reflectometer may be used.

In an embodiment, the spectrometer 120 may be communicatively coupled to a processor 125. The processor 125 in FIG. 1A is adjacent to the spectrometer 120 and near an edge of the board 110. However, it is to be appreciated that the processor 125 may be provided at any desired location. In an embodiment, the processor 125 may be communicatively coupled to the spectrometer 120 by any suitable interconnect architecture. In one embodiment, cables or flex circuits (not shown) are provided between the spectrometer 120 and the processor 125. In other embodiments, the spectrometer 120 may be coupled to the processor 125 through the board 110.

The processor 125 may include a die suitable for processing the spectrums obtained by the spectrometer 120. The processor 125 may also include functionality in order to control and/or process the data from the spectrometer 120. For example, the processor 125 may dictate to the spectrometers 120 when to collect data. In embodiments with a light source 122, the processor 125 may also control the light source. In an embodiment, the light sources 122 may be any suitable light source architecture. In a particular embodiment, the light sources 122 are light emitting diodes (LEDs), though light sources with different spectrums may be included in other embodiments.

The processor 125 may include a memory or use external memory for storing data. In other embodiments, the processor 125 may include a wireless communication interface (e.g., a wireless transceiver) in order to transmit data (either raw spectrum data or processed data) to an external device. Though, a wired input/output connection may also be used to send and/or receive data when the sensor 100 is hardwired to the processing chamber. In an embodiment, the sensor 100 may be powered by a power source 127. The power source 127 may be a battery or the like. Though, in some embodiments, the sensor 100 may be directly wired to power on the processing chamber, and a dedicated power source 127 may not be needed.

In an embodiment, the sensor 100 may further comprise a housing 111. The housing 111 may be a material that is resistant to the processing conditions within a given chamber. The housing 111 protects the internal components of the sensor 100 from damage. For example, the housing 111 may be a ceramic material, a metallic material, or any other suitable material. The housing 111 may have a form factor that allows for easy integration into various locations within a chamber. For example, the housing 111 may have a form factor that is approximately 75 mm by approximately 75 mm by approximately 15 mm. Though, smaller or larger form factors may also be provided. In an embodiment, a window 112 may be provided in the housing 111. The window 112 may be optically clear.

In FIG. 1A, the sensor 100 is illustrated as being a stationary sensor that is configured to be mounted at various locations within a processing tool. However, embodiments are not limited to such configurations. For example, the board 110 may have a wafer form factor (e.g., 200 mm, 300 mm, 450 mm, etc.) or any other form factor. The sensor 100 on a wafer form factor board 110 may be inserted and withdrawn from the chamber in order to provide spatial monitoring throughout the chamber. In this manner, the sensor 100 may be described as an instrumented substrate, such as an instrumented wafer.

Referring now to FIG. 1B, a cross-sectional illustration of a sensor 100 is shown, in accordance with an additional embodiment. In an embodiment, the sensor 100 in FIG. 1B may be substantially similar to the sensor 100 in FIG. 1A, with the exception of the size of the board 110 and the layout of the components. Instead of having all components on one side of the board 110, one or more components may be moved to the backside of the board 110. For example, the processor 125 and the power source 127 may be moved to the backside of the board 110. In such embodiments, vias (not shown) may be provided through the board 110 in order to communicatively and electrically couple components together. Moving one or more components to the backside of the board 110 allows for size reduction of the board 110. Though, such embodiments may be at the cost of a thicker Z-height. In an embodiment, a window 112 may be provided in the housing 111. The window 112 may be optically clear.

Referring now to FIG. 1C, a plan view illustration of a sensor 100 is shown, in accordance with an embodiment. The sensor 100 may include a housing 111. The housing 111 may have a window 112 that is provided over the spectrometer 120. One or more light sources 122 may also be exposed by the window 112. The window 112 may be optically clear. This allows for electromagnetic radiation to be passed through the housing 111. For example, the window 112 may be any optically clear material, such as sapphire, quartz, or the like. In some embodiments, the window 112 may also include an antireflective coating. In the illustrated embodiment, the window 112 is shown as being circular. Though rectangular or other shaped windows may be used. Additionally, while a single window 112 is shown in FIG. 1C, multiple windows 112 may be used. For example, where multiple spectrometers 120 are distributed across the board 110, each spectrometer 120 may have a dedicated window. While a window 112 is shown in FIG. 1C, it is to be appreciated that the housing 111 may include a material that is optically clear (e.g., sapphire, quartz, etc.). In such instances, a dedicated window 112 may be omitted since the entire housing 111 is optically clear.

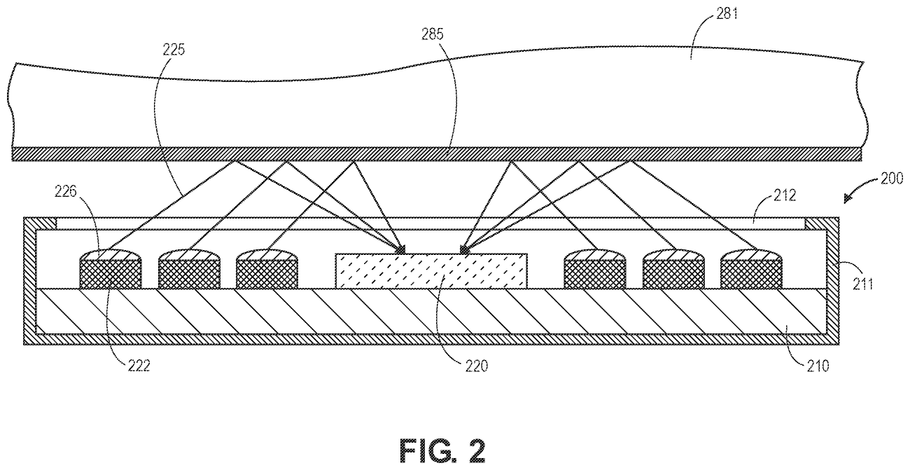

Referring now to FIG. 2, a cross-sectional illustration of a sensor 200 inside a chamber body 281 is shown, in accordance with an embodiment. In a particular embodiment, a layer 285 may be deposited on an interior surface of the chamber body 281. The layer 285 may be a conditioning layer, or may be the result of deposition of byproducts of a processing operation (e.g., etch byproducts, redeposition, etc.) While shown as a single layer 285, it is to be appreciated that multiple layers of different materials may also be included as part of the layer 285.

In an embodiment, the sensor 200 may be integrated into a portion of the chamber. For example, the sensor 200 may be provided as part of a chamber wall, a liner, a lid, a pedestal, or the like. In an embodiment, the sensor 200 may include a housing 211 with a window 212. In an embodiment, a board 210 may be provided within the housing 211. In an embodiment, a spectrometer 220 is shown on the board 210.

In an embodiment, a plurality of light sources 222 may be provided on the board 210. In an embodiment, the light sources 222 may each be optically coupled to the single spectrometer 220. For example, optical paths 225 start at each of the light sources 222, reflect off of different locations on the layer 285, and end at the spectrometer 220. As such, a plurality of locations across the layer 285 may be analyzed without needing to laterally move the sensor 200. Each of the light sources 222 may include a lens 226 to focus the light so that the optical paths 225 end at the spectrometer 220. In the illustrated embodiment, six light sources 222 are shown. However, it is to be appreciated that any number of light sources 222 (e.g., two or more light sources 222) may be used in order to provide spatial analysis of the layer 285.

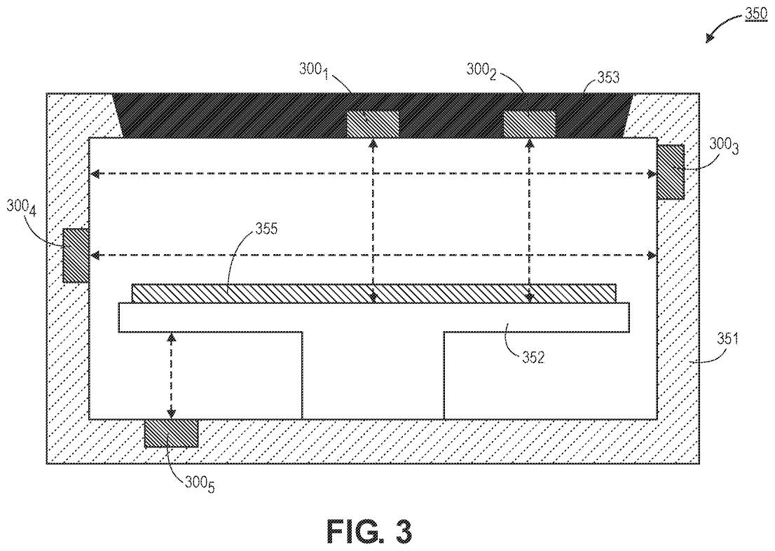

Referring now to FIG. 3, a cross-sectional illustration of a chamber 350 is shown, in accordance with an embodiment. In an embodiment, the chamber 350 may include a chamber body 351. The chamber body 351 may include an enclosure for processing semiconductor substrates (e.g., wafers) 355 or the like. In the illustrated embodiment, the chamber body 351 is shown as a substantially monolithic chamber. However, it is to be appreciated that plasma processing chambers 350 may include separate components to fabricate the chamber body 351. For example, a lid or showerhead 353 may be provided as a distinct component from sidewalls of the chamber body 351. In an embodiment, other components may be provided within the chamber body 351. For example, chamber liners, process rings, etc. may be included within the chamber body 351. In an embodiment, a pedestal 352 may be used to support substrates 355.

In an embodiment, the chamber 350 may be any chamber suitable for processing semiconductor substrates or other substrates useful in the semiconductor manufacturing context. For example, the chamber 350 may be a plasma chamber, such as a plasma deposition or a plasma etching chamber. In other embodiments, the chamber 350 may be a chemical vapor deposition (CVD) chamber, an atomic layer deposition (ALD) chamber, a physical vapor deposition (PVD) chamber, a thermal treatment chamber (e.g., a rapid thermal processing (RTP) chamber), a CMP tool with polishing pad, or any other processing chamber used in semiconductor processing environments. In an embodiment, the chamber 350 may be one chamber in a cluster tool. That is, a plurality of chambers 350 may be coupled together through a central chamber.

In an embodiment, an array of sensors 300 may be provided throughout the chamber 350. For example, five sensors 3001-3005 are shown in FIG. 3. The sensors 300 are integrated into or on a plurality of different chamber 350 components. As used herein “integrated into” may refer to a sensor that is embedded, partially embedded, or set into a cavity of a surface of a component in the chamber 350. Integration may also refer to electrical coupling (e.g., to provide power or data communication).

In an embodiment, a first sensor 3001 and a second sensor 3002 may be integrated with the lid 353. The sensors 3001 and 3002 may have sensors that face down toward the pedestal 352, as indicated by the dashed lines. In some embodiments, surfaces of the pedestal 352 can be investigated when a substrate 355 is not present. Lid 353 sensors 3001 and 3002 may also be used to investigate properties of a plasma formed in the chamber 350 above the pedestal 352. The sensor 3001 may analyze a center of the plasma, and the sensor 3002 may analyze an edge of the plasma in order to determine center-to-edge differences in the plasma.

In an embodiment, a third sensor 3003 and a fourth sensor 3004 may be integrated with sidewalls of the chamber body 351. The third sensor 3003 and the fourth sensor 3004 may be oriented to determine surface conditions on chamber body 351 on opposite sides of the chamber 350. Additionally, the offset heights of the third sensor 3003 and the fourth sensor 3004 may be used to determine top-to-bottom differences in the plasma. In an embodiment, a fifth sensor 3005 may be provided along a bottom of the chamber body 351. The fifth sensor 3005 may monitor a portion of the pedestal 352 or other surfaces below the substrate 355. In some embodiments, sensors 300 may also be configured to provide measurement of surfaces of the lid 353.

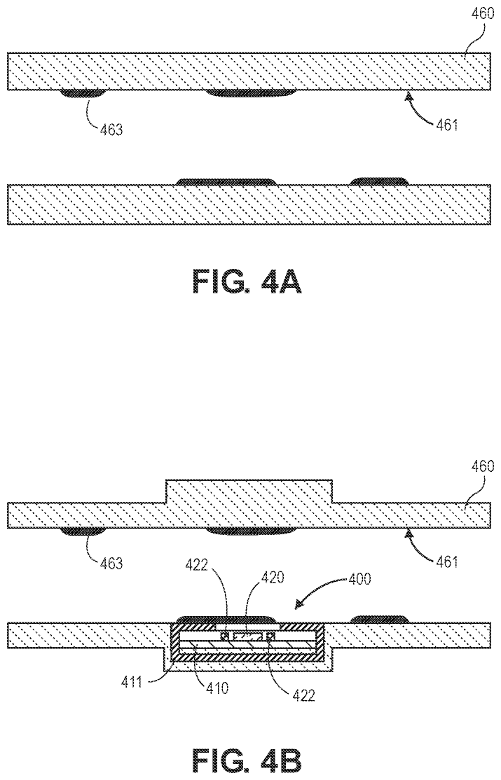

In addition to monitoring the chamber 350, embodiments may also include the ability to monitor gas lines 460 that feed into the chamber 350. For example, in FIG. 4A, a cross-sectional illustration of a gas line 460 is shown. In an embodiment, the gas line 460 may be part of a source gas system that provides gasses into the chamber 350. In other embodiments, the gas line 460 may be part of an exhaust line that removes gasses and other byproducts from the chamber 350.

In an embodiment, the gas line 460 may comprise an interior surface 461. During the flow of gasses over the interior surface 461, deposits 463 may form on the interior surface 461. The deposits 463 may impact the flow of gasses through the gas line 460 or be a source for contamination of the gas that is desired to be flowing through the gas line 460. As such, it is desirable to monitor the interior surfaces 461 of the gas line 460 (e.g., to determine material composition and/or thickness of the deposits 463).

Referring now to FIG. 4B, a cross-sectional illustration of a gas line 460 is shown, in accordance with an embodiment. As shown, the gas line 460 may include an integrated sensor 400. As shown, the sensor 400 may be within a thickness of the gas line 460 so that the top surface of the gas line 460 is substantially coplanar with the interior surface 461 of the gas line 460. Though, the top surface of the sensor 400 may be above or set back from the interior surface 461 of the gas line 460. As shown, the thickness of the wall of the gas line 460 may be non-uniform. For example, a thicker portion of the gas line 460 may be provided to accommodate the sensor 400. In some embodiments, the thicker portion may be a coupling unit that includes the sensor 400. The coupling unit may connect to the gas line 460 on the left side and the right side. That is the sensor 400 may be a discrete component from the gas line 460.

In an embodiment, the sensor 400 may be similar to any of the sensor architectures described in greater detail herein. For example, the sensor 400 may comprise a board 410. A spectrometer 420 and one or more light sources 422 may be on a surface of the board 410. Other components like a processor, a power source, a communication module, etc. may also be included on the board 410. In an embodiment, board 410, spectrometer 420, and light sources 422 may be surrounded by a housing 411. A window 412 may be provided in the housing 411 in order to allow light from the light sources 422 to pass into the interior of the gas line 460 and reflect back to the spectrometer 420.

Referring now to FIG. 4C, a cross-sectional illustration of a gas line 460 is shown, in accordance with an additional embodiment. In an embodiment, the gas line 460 may be substantially similar to the gas line 460 in FIG. 4A, with the addition of a sensor 400. Instead of integrating the sensor 400 into the wall of the gas line 460 (e.g., similar to FIG. 4B), the sensor 400 may be provided outside of the gas line 460. A window 465 through a thickness of the gas line 460 may provide an optical inlet/outlet in order to investigate the internal surface 461 of the gas line 460. A sensor 400 may be provided on the outside surface of the window 465. The sensor 400 may be substantially similar to the sensor 400 described above with respect to FIG. 4B.

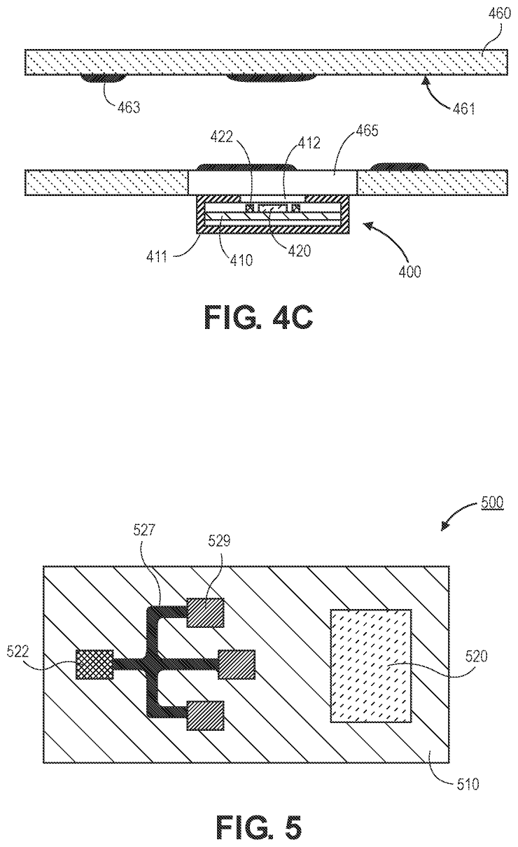

Referring now to FIG. 5, a plan view illustration of a sensor 500 is shown, in accordance with an additional embodiment. As shown, the sensor 500 includes a board 510. In the illustrated embodiment, only the light source 522, a set of repeaters 529 or additional light sources, and a spectrometer 520 are shown for simplicity. However, the sensor 500 may also include a processor, a power source, and the like, similar to embodiments described above.

In an embodiment, a single light source 522 may be used in order to feed light to a plurality of repeaters 529. For example, three repeaters are shown in FIG. 5. Each of the repeaters 529 may be coupled to different spectrometers 520. In other embodiments, multiple repeaters 529 may be coupled to a single spectrometer 520. In an embodiment, the repeaters 529 are optically coupled to the light source 522 by optical waveguides 527. The repeaters 529 may include a lens or the like in order to optically couple with the spectrometers 520.

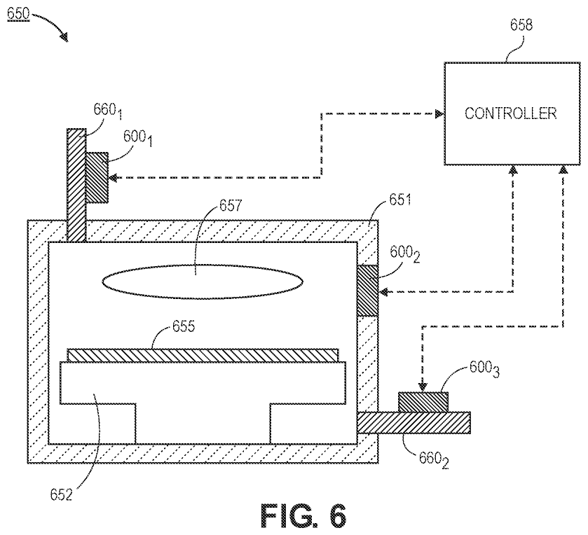

Referring now to FIG. 6, a cross-sectional illustration of a system 650 is shown, in accordance with an embodiment. As shown, the system 650 may comprise a chamber body 651. A gas inlet 6601 and a gas outlet 6602 may be coupled to the chamber body 651. A pedestal 652 may support a substrate 655 below a plasma 657. In an embodiment, the system 650 may comprise a plurality of sensors 6001-6003. The sensors 600 may be similar to any of the sensor architectures described in greater detail herein. For example, the sensors 600 may comprise a spectrometer. The sensors 600 may be small form factor devices. As such, the sensors 600 may be integrated into various locations throughout the system 650.

In an embodiment, a first sensor 6001 is coupled to the gas inlet 6601, and a second sensor 6002 is integrated into the chamber body 651 to sense one or more properties within the chamber body 651. While shown as being on the sidewall, it is to be appreciated that sensors 600 may be formed at any location within the chamber body 651 (e.g., sidewall, lid, liner, process ring, bottom, etc.). Also, while a single second sensor 6002 is shown, it is to be appreciated that an array of sensors may be integrated with the chamber body 651, similar to embodiments described above. In an embodiment, a third sensor 6003 may be provided on the gas outlet 6602.

In an embodiment, the sensors 600 may be communicatively coupled to a controller 658 (as indicated by the dashed lines). The communication coupling may be implemented wirelessly or through a hardwire connection. The controller 658 may be used to control processing parameters within the chamber body 651 (e.g., pressures, temperatures, plasma properties, etc.). The controller 658 may use feedback data generated by one or more of the sensors 600 in order to modify process parameters in order to improve the uniformity of various substrate 655 outcomes (e.g., to improve layer thickness uniformity or the like).

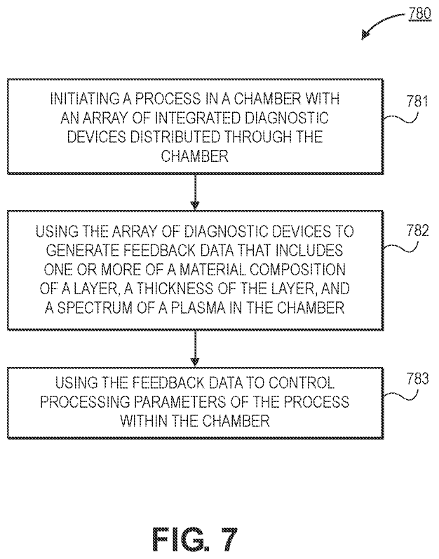

Referring now to FIG. 7, a process flow diagram of a process 780 implemented in a chamber is shown, in accordance with an embodiment. In an embodiment, the process 780 may begin with operation 781, which comprises initiating a process in a chamber with an array of integrated diagnostic devices distributed throughout the chamber. The diagnostic devices may be sensors similar to any of the sensors described in greater detail herein. For example, sensors may be integrated into the chamber body at various locations (e.g., wall, lid, liner, bottom, process ring, etc.). The sensors may also be included in gas inlets or gas outlets (i.e., exhausts). The sensors may comprise spectrometers and, optionally, light sources. The form factor of the sensors may be such that the sensors can be easily integrated within the various locations of the chamber. In some embodiments, the sensors are wirelessly coupled to a controller, or are hardwired to a controller.

In an embodiment, the process in the chamber may be any process suitable for semiconductor manufacturing operations. For example, the process may be a deposition process (e.g., ALD, CVD, or PVD, all of which may be implemented with or without a plasma), an etching process, or a treatment process (e.g., heat treatment, plasma treatment, etc.) or polishing process (CMP). In a particular embodiment, the process may be a chamber cleaning or chamber seasoning process. A chamber cleaning or seasoning process may be implemented to modify the coating along an interior surface of the chamber.

In an embodiment, the process 780 may continue with operation 782, which comprises using the array of diagnostic devices to generate feedback data that includes one or more of a material composition of a layer, a thickness of the layer, and a spectrum of a plasma in the chamber. These feedback data types can be used to improve process outcomes on the wafer within the chamber. Additionally, since an array of diagnostic devices are used, spatial mapping of the chamber and/or plasma can be obtained. As such, parameters such as center-to-edge measurements can also be generated as part of the feedback data in order to provide even better wafer uniformity results.

In an embodiment, the process 780 may continue with operation 783, which comprises using the feedback data to control processing parameters of the process within the chamber. For example, the feedback data may be used as an input to control processing parameters, such as, but not limited to, gas flow rates, pressures, temperatures, voltages of different electrodes, and the like.

In a particular embodiment, the feedback data may be used in order to provide closed loop control of the process within a chamber. That is, the feedback data may be repeatedly supplied to a controller in order to modify the process parameters throughout the process implemented in the chamber. In some embodiments, the feedback data may be used as an endpoint detection. For example, when a layer reaches a particular thickness or material composition, the process may be ended.

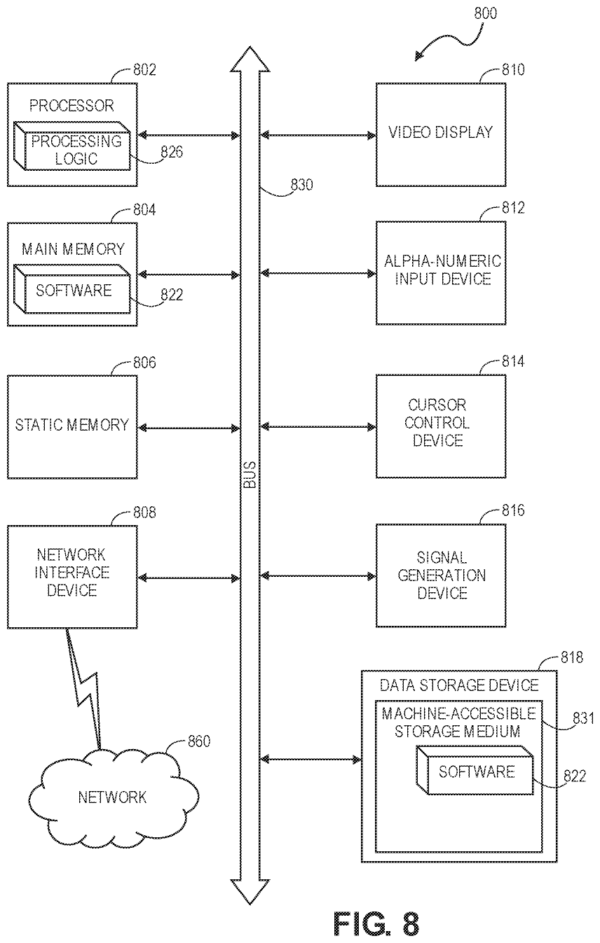

Referring now to FIG. 8, a block diagram of an exemplary computer system 800 of a processing tool is illustrated in accordance with an embodiment. In an embodiment, computer system 800 is coupled to and controls processing in the processing tool. Computer system 800 may be connected (e.g., networked) to other machines in a Local Area Network (LAN), an intranet, an extranet, or the Internet. Computer system 800 may operate in the capacity of a server or a client machine in a client-server network environment, or as a peer machine in a peer-to-peer (or distributed) network environment. Computer system 800 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 800, the term “machine” shall also be taken to include any collection of machines (e.g., computers) that individually or jointly execute a set (or multiple sets) of instructions to perform any one or more of the methodologies described herein.

Computer system 800 may include a computer program product, or software 822, having a non-transitory machine-readable medium having stored thereon instructions, which may be used to program computer system 800 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 800 includes a system processor 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a secondary memory 818 (e.g., a data storage device), which communicate with each other via a bus 830.

System processor 802 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 802 may also be one or more special-purpose processing devices such as an application specific integrated circuit (ASIC), a field programmable gate array (FPGA), a digital signal system processor (DSP), network system processor, or the like. System processor 802 is configured to execute the processing logic 826 for performing the operations described herein.

The computer system 800 may further include a system network interface device 808 for communicating with other devices or machines. The computer system 800 may also include a video display unit 810 (e.g., a liquid crystal display (LCD), a light emitting diode display (LED), or a cathode ray tube (CRT)), an alphanumeric input device 812 (e.g., a keyboard), a cursor control device 814 (e.g., a mouse), and a signal generation device 816 (e.g., a speaker).

The secondary memory 818 may include a machine-accessible storage medium 832 (or more specifically a computer-readable storage medium) on which is stored one or more sets of instructions (e.g., software 822) embodying any one or more of the methodologies or functions described herein. The software 822 may also reside, completely or at least partially, within the main memory 804 and/or within the system processor 802 during execution thereof by the computer system 800, the main memory 804 and the system processor 802 also constituting machine-readable storage media. The software 822 may further be transmitted or received over a network 860 via the system network interface device 808. In an embodiment, the network interface device 808 may operate using RF coupling, optical coupling, acoustic coupling, or inductive coupling.

While the machine-accessible storage medium 832 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A semiconductor processing tool, comprising:
a chamber; and
a diagnostic device integrated with the chamber, wherein the diagnostic device comprises:
a board;
a spectrometer on the board; and
a housing around the board.

2. The semiconductor processing tool of claim 1, wherein the diagnostic device is integrated into a wall, a lid, a chuck, or a liner of the chamber.

3. The semiconductor processing tool of claim 1, wherein the diagnostic device is integrated into a gas line into or out of the chamber.

4. The semiconductor processing tool of claim 1, further comprising:
a plurality of diagnostic devices integrated with the chamber.

5. The semiconductor processing tool of claim 1, further comprising:
a light source on the board.

6. The semiconductor processing tool of claim 5, wherein a plurality of light sources are configured to be optically coupled to the spectrometer.

7. The semiconductor processing tool of claim 1, further comprising:
a plurality of spectrometers on the board.

8. The semiconductor processing tool of claim 1, wherein the housing comprises a window, and wherein the window is optically clear and/or wherein the window is coated with an antireflective coating.

9. The semiconductor processing tool of claim 1, wherein the diagnostic device includes an internal power source.

10. The semiconductor processing tool of claim 1, wherein the diagnostic device comprises a wireless transceiver.

11. A semiconductor processing tool, comprising:
a chamber; and
a set of diagnostic devices integrated with the chamber, wherein the integrated diagnostic devices are configured to provide layer thickness measurements, layer composition measurements, and/or plasma property measurements.

12. The semiconductor processing tool of claim 11, wherein the set of integrated diagnostic devices are configured to provide a spatial map of layer thickness, a spatial map of plasma properties, and/or a spatial map of layer composition within the chamber.

13. The semiconductor processing tool of claim 11, wherein the set of diagnostic devices comprises a plurality of spectrometers and/or reflectometers.

14. The semiconductor processing tool of claim 13, wherein the set of diagnostic devices comprise one or more light sources.

15. The semiconductor processing tool of claim 12, wherein the set of diagnostic devices comprises at least one diagnostic device along a gas inlet line and/or an exhaust line.

16. A method of processing a semiconductor device, comprising:
initiating a process in a chamber with an array of integrated diagnostic devices distributed through the chamber;
using the array of diagnostic devices to generate feedback data that includes one or more of a material composition of a layer, a thickness of the layer, and a spectrum of a plasma in the chamber; and
using the feedback data to control processing parameters of the process within the chamber.

17. The method of claim 16, wherein the process is a chamber cleaning process or a chamber seasoning process.

18. The method of claim 16, wherein the determining the spectrum of the plasma includes finding a spatial distribution of plasma species within the chamber.

19. The method of claim 16, wherein the feedback data is used to provide closed loop control of the process.

20. The method of claim 16, further comprising:
ending the process when the material composition and/or thickness of the layer or spatial distribution of spectrum is at a predetermined value.
